(19) United States
(12) Patent Application Publication
(10) Pub. No.: US 2011/0279984 A1
(43) Pub. Date: Nov. 17, 2011

(54) ELECTRONIC MODULE WITH SEAMLESS ANTI-EMI DEVICE

(75) Inventors: PING-SHENG SU, New Taipei (TW); XIAO-LI LI, Kunshan (CN)

(73) Assignee: HON HAI PRECISION INDUSTRY CO., LTD., New Taipei (TW)

(21) Appl. No.: 13/105,934

(22) Filed: May 12, 2011

(30) Foreign Application Priority Data
May 12, 2010 (CN) 201020187756.9

(51) Int. Cl. H05K 7/14; H05K 7/02

(52) U.S. Cl. 361/736; 361/728

(57) ABSTRACT

An electronic module (100) includes a housing having an outer surface and a metallic gasket (5) attached to the housing and substantially covering the outer surface. The gasket (5) includes an outer configuration with a plurality of elastic detents (52) and a unitary inner configuration with a seamless sheet (51).

### BACKGROUND OF THE INVENTION

1. Field of the Invention

The present invention generally relates to an electronic module, and more particularly to an electronic module having a metallic gasket for suppressing Electro-Magnetic Interference (EMI).

2. Description of Related Art

A small form factor pluggable (SFP) module is widely used in signal transmission. This kind of module usually includes a plug connector connecting to an end of a cable and a receptacle connector mounted on the circuit substrate. The plug connector and the receptacle connector have metal shells or conductive shells to reduce EMI. However, as a gap exists between an interface of the plug connector and the receptacle connector, and the EMI phenomena can not be completely eliminated, so other method is proposed to settle this problem. U.S. Pat. Pub. No. 20070117458 A1 discloses an EMI-minimized transceiver, rectangular shaped collar (gasket) including a plurality of contact fingers (detents) for making electrical contact with a chassis in which a transceiver cage comprising the collar and the cage body is mounted.

The aforementioned EMI-minimized collar may help reducing EMI, however, as a slit is formed between two adjacent detents, some EMI leakage still passes through the slit.

Hence, an improved electronic module is highly desired to overcome the disadvantages of the related art.

### SUMMARY OF THE INVENTION

Accordingly, an object of the present invention is to provide an electronic module using an improved metallic gasket suppressing Electro-Magnetic Interference (EMI).

In order to achieve the object set forth, an electronic module comprising a housing having an outer surface and a metallic gasket attached to the housing and substantially covering the outer surface. The gasket includes an outer configuration with a plurality of elastic detents and a unitary inner configuration with a seamless sheet.

Other objects, advantages and novel features of the invention will become more apparent from the following detailed description when taken in conjunction with the accompanying drawings.

### BRIEF DESCRIPTION OF THE DRAWINGS

FIG. 1 is an assembled, perspective view of an electronic module in accordance with the present invention;

FIG. 2 is a view similar to FIG. 1, but viewed from another aspect;

FIG. 3 is an exploded, perspective view of the electronic module shown in FIG. 1;

FIG. 4 is a view similar to FIG. 3, but viewed from another aspect;

FIG. 5 is a cross-section view taken along line 5-5 of FIG. 1; and

FIG. 6 is an enlarged perspective view of a gasket of the electronic module shown in FIG. 2.

### DETAILED DESCRIPTION OF THE INVENTION

Reference will now be made in detail to the preferred embodiment of the present invention.

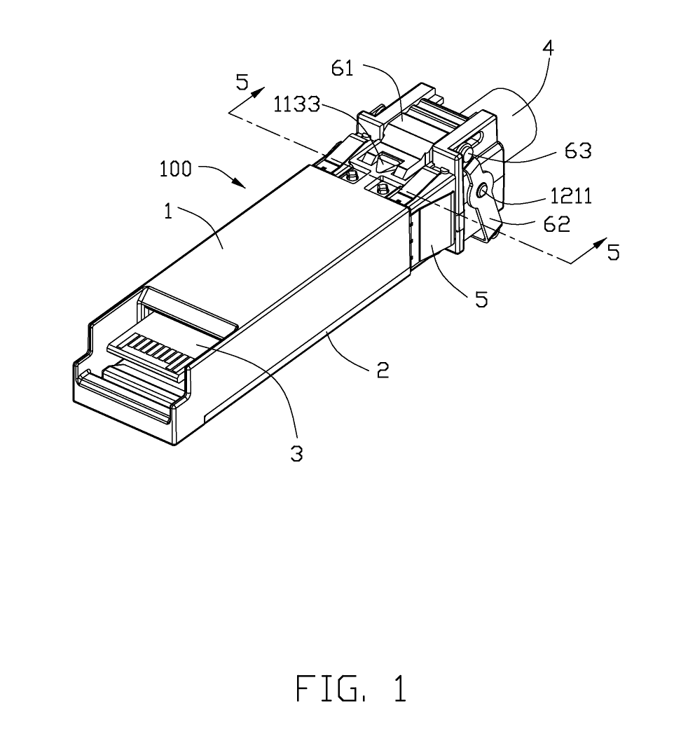

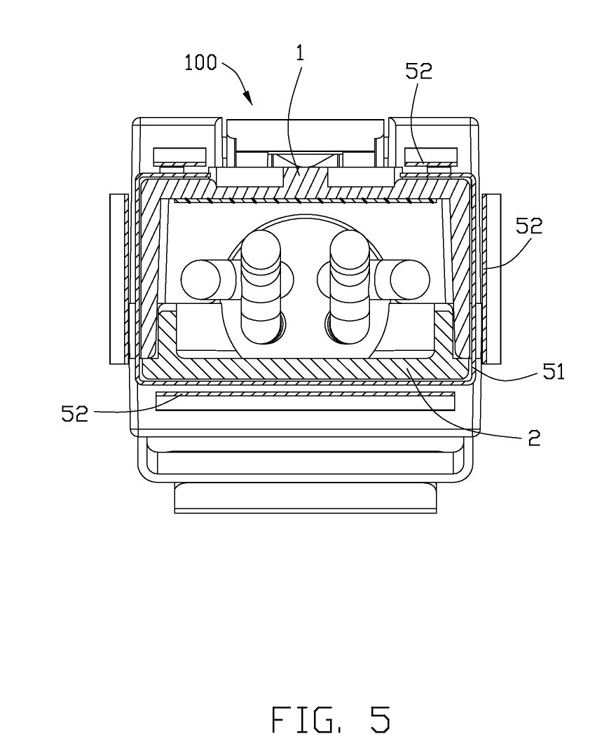

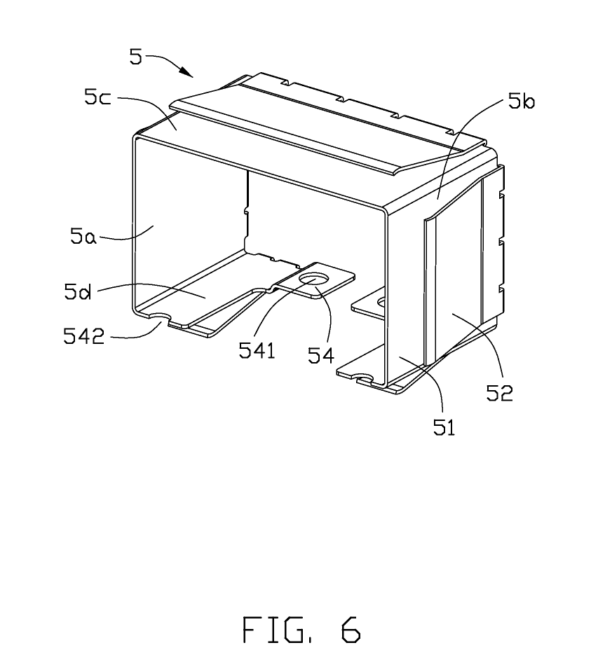

Referring to FIGS. 1-6, the electronic module 100 comprises a housing (not numbered) composed of a conductive base portion 1 and a conductive panel portion 2, a printed circuit board 3, a cable 4, a metallic gasket 5 and an actuator mechanism (not numbered).

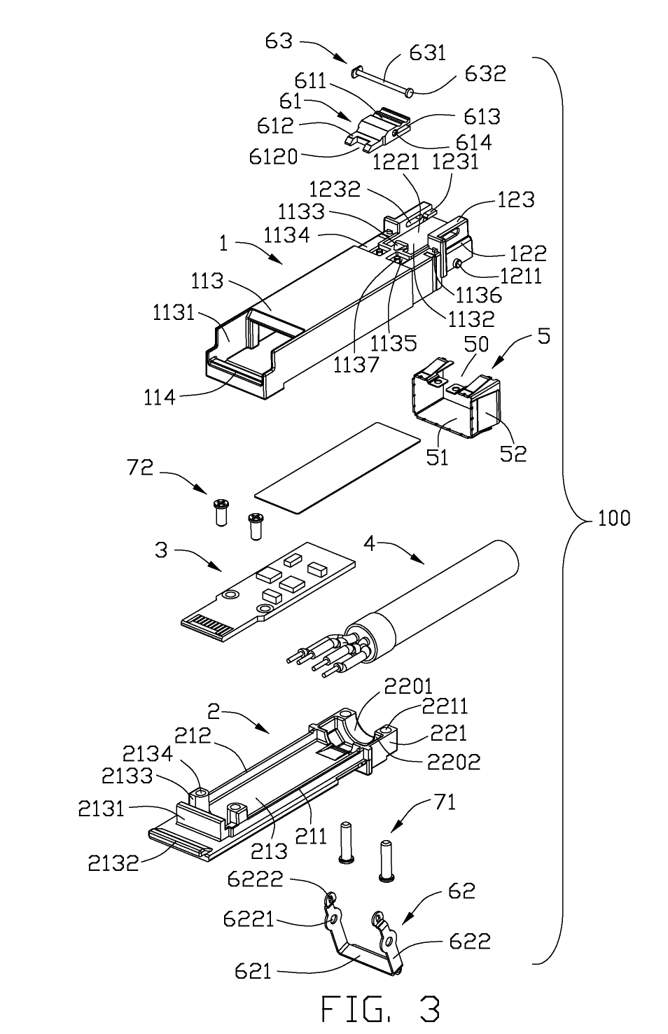

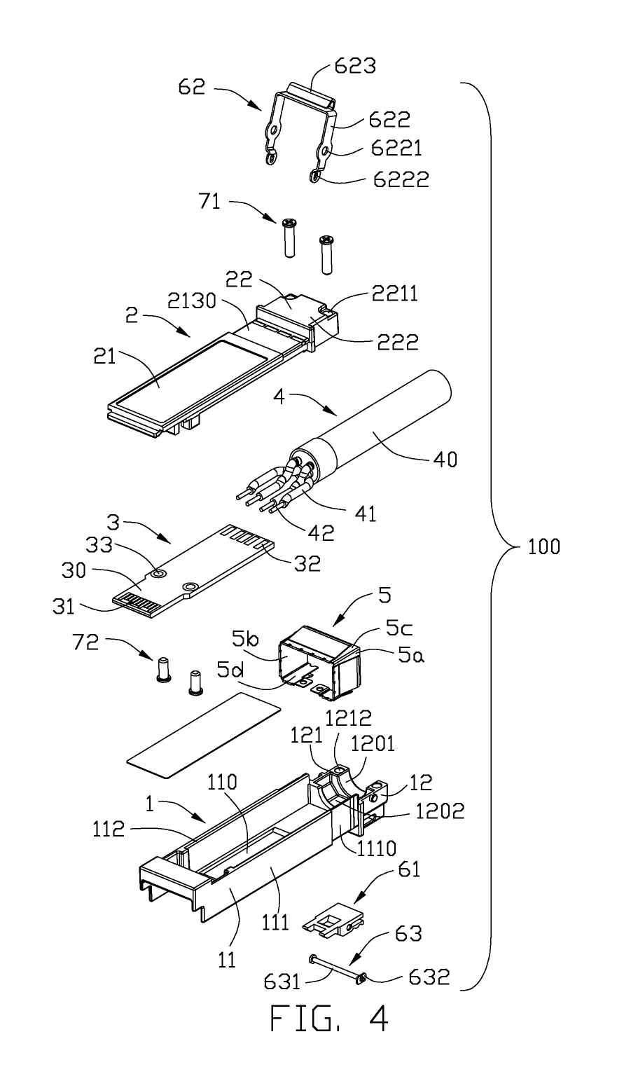

Referring to FIGS. 3-4, the base portion 1 is die-cast or other metallic plated body, and includes a primary body portion 11 and a first mounting portion 12 rearward extending from back face of the primary body portion 11. The primary body portion 11 has a pair of lateral walls 111, 112 and a bottom wall 113 joining to lower sections of the lateral walls 111, 112 to from a receiving space 110 with an upper window (not numbered). Rear sections of the pair of the lateral walls 111, 112 define a pair of first depression portions 1110. A front section of the bottom wall 113 is cut to form an outlet 1131. A rear section of the bottom wall 113 defines a first channel 1132 located in a middle area thereof, with a tab 1133 formed in the front of the first channel 1132. A pair of sunken portions 1134 are defined in two lateral areas of the rear section of the bottom wall 113, and arranged at outward of the first channel 1132. A pair of indentations 1135 are arranged at inward of the corresponding sunken portions 1134, and the indentations 1135 are deeper than the sunken portions 1134. A pair of protrusions 1136 are respectively formed in a rear corners (not numbered) of the sunken portions 1134, a pair of tiny posts 1137 respectively are formed in forward corners (not numbered) of the pair of depression portions 1134, and a pair of protrusion members 1136 are respectively formed in a central of the indentations 1135. The primary body portion 11 further has a beam portion 114 with substantially L-shaped cross-section interconnecting distal portions of the pair of the lateral walls 111, 112.

The first mounting portion 12 has a pair of side walls 121 and a lower wall 122 to corporately form a first semi-circular cavity 1201, and a deeper first position slot 1202 is located in front of the first semi-circular cavity 1201. A second channel 1221 is defined in a middle area of the lower wall 122 and communicated with the first channel 1132 of the primary body portion 11. A pair of guiding members 123 are respectively formed on lateral areas of the lower wall 122. Each guiding member 123 has a thin bar member 1231 formed on a back section of an interior surface thereof and a lengthways guiding passage 1232 in front of the bar member 1231. A pair of pivot members 1211 are respectively formed on upper sections of exterior surfaces of the pair of side walls 121. A pair of screw holes 1212 are respectively recessed downwards from upper surfaces of rear sections of side walls 121.

The panel portion 2 is die-cast or a metallic plated body, and includes a secondary body portion 21 and a second mounting portion 22 extending rearwards from a back face of the secondary body portion 21. The secondary body portion 21 has a planar board member 213 and a pair of flange members 211, 212 formed on a bottom surface thereof laterally. The board member 213 defines a second depression portion 2130 on an upper section thereof and a vertical wall 2131 on a front section thereof. A pair of supporting posts 2133 are located at back end of the vertical wall 2131, and each supporting post 2133 further defines a second screw hole 2134 therein. The board member 213 has a protrusion portion 2132 on a front end thereof. The second mounting portion 22 has a pair of side walls 221 and an upper wall 222 to corporately form a second semi-circular cavity 2201, and a second position slot 2202 is arranged in front of the second semi-circular cavity 2201. A pair of trough holes 2211 are defined in a rear segment of the corresponding side walls 221.

The panel portion 2 further includes a second mounting portion 22 rearward extending from a back face of the secondary body portion 21. The second mounting portion 22 also has a pair of side walls 221 and a lower wall 222 to corporately form a second semi-circular cavity 2201 and a deeper second position slot 2202 located in front of the second semi-circular cavity 2201. A pair of through holes 2211 are respectively defined in a rear section of the side walls 221.

The printed circuit board 3 includes a substrate 30, a plurality of first conductive pads 31 arranged on a front section of the substrate 30 and a plurality of second conductive pads 32 located on rear section thereof. A pair of positioning holes 33 are disposed in the substrate 30, and proximate a front section of the substrate 30.

The cable 4 includes an outer insulative jacket 40, and a number of wires 41 enclosed in the insulative jacket 40 and insulated from each other. Each of the wires 41 further has an inner conductor 42 for transmitting signal.

The actuator mechanism includes a slider member 61, an actuator member 62 and a fastening member 63. The slider member 61 has a substantially rectangular shaped body portion 611 and two wedge-shaped arm portions 612 extending forward from a front face of the body portion 611. The two arm portions 612 are spaced from each other, with an opening 6120 formed therebetween. The body portion 611 has two grooves 613 respectively recessed inward from lateral surfaces of a rear segment thereof and a transverse through hole 614 in a middle section thereof, the transverse through hole 614 is adjacent to the grooves 613. The actuator member 62 is configured to doorframe-shaped, and includes a doorhead 621 and two door jambs 622. A curved handle member 623 is formed at a rear edge of the doorhead 621 and protruding upwardly. Each door jamb 622 defines a first positioning hole 6221 in a middle section thereof, and a pair of mounting holes 6222 are defined through the lower ends of the door jambs 622. The fastening member 63 is of rod-shaped, and includes a bolt member 631 and a nut 632.

Referring to FIGS. 3-6, the gasket 5 is made of metallic sheet and comprises an outer configuration and an inner configuration. The inner configuration is configured a seamless anti-EMI device and defined as a rectangular-shaped frame portion 51, and the frame portion 51 includes a pair of vertical sides 5a, 5b, an upper side 5c joining upper edges of the pair of vertical sides 5a, 5b, and a pair of lower sub-walls 5d respectively extending inwardly from lower edges of the pair of vertical walls 5a, 5b. A lower outlet 50 is formed between the pair of lower sub-walls 5d for assembling easily. The vertical sides 5a, 5b, the upper side 5c and the lower sub-walls 5d are pressed of a metallic sheet to form a unitary configuration without any seam therein, therefore to achieve better Electro-Magnetic Interference (EMI) suppressing effect.

The frame portion 51 is shielding with a plurality of elastic detents 52, and the elastic detents 52 are interconnecting with the frame portion 51, that is to say, the elastic detents 52 and the frame portion 51 are made of a same metallic sheet. The elastic detents 52 are bent outwards and extending rearwards from front edges of the frame portion 51, and shielding the vertical sides 5a, 5b, the upper side 5c and the lower sub-walls 5d respectively.

A pair of fixing portions 54 are formed on free ends of the pair of lower sub-walls 5d, and extending breadthwise into the lower outlet 50. Each fixing portion 54 has a circular hole 541 in a central area thereof. Each sub-wall 5d has a semi-circular cutout 542 located in a distal end thereof to accommodate corresponding protrusion members 1136 in the sunken portions 1134.

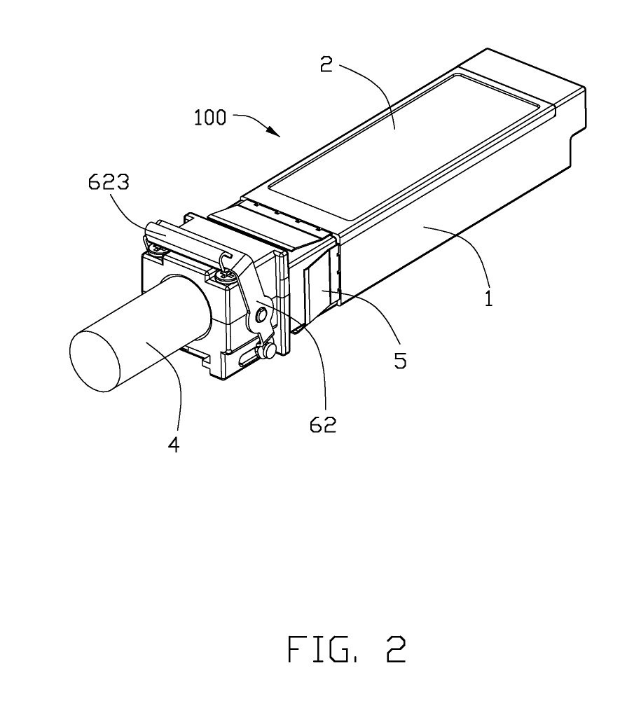

Referring to FIGS. 1-2, in conjunction with FIGS. 3-6, when assembly, the insulative jacket 40 of a front segment of the cable 4 is decorticated and then the wires 41 are exposed outside, and then front section of the inner conductors 42 are made to expose outward. The inner conductors 42 are soldered to the second conductive pads 32 of the printed circuit board 3. The printed circuit board 3 is put on the pair of supporting posts 2133 of the panel portion 2, with the pair of positioning holes 33 thereof aligning with the pair of second screw holes 2134 of the pair of supporting posts 2133, and then a pair of second screw members 72 are inserted into the pair of positioning holes 33 and the pair of second screw holes 2134 to fix the printed circuit board 3 to the panel portion 2. Partial of the cable 4 is received in the second position slot 2202 of the panel portion 2. The panel portion 2 is assembled to the base portion 1, with a pair of lateral flange members 211, 212 thereof inserted into the receiving space 110, the protrusion portion 2132 is supported by the beam portion 114 of the base portion 1. Simultaneously, the printed circuit board 3 is received in the receiving space 110, the cable 4 is partially received in the first position slot 1202, the pair of through holes 2211 of the panel portion 2 are aligning with a pair of screw holes 1212 of the base portion 1, then a pair of first screw members 71 are inserted into the through holes 2211 and the screw holes 1212 to fasten the panel portion 2 and the base portion 1 together.

The gasket 5 is assembled to an outer surface of the housing, with the pair of vertical sides 5a, 5b thereof located in the pair of first depression portions 1110 of the base portion 1, the upper side 5c thereof located in the second depression portion 2130 of the panel portion 2, the pair of lower sub-walls 5d are located in the pair of sunken portions 1134, the fixing portions 54 are accommodated in the corresponding indentations 1135. The pair of tiny posts 1137 are inserted into the pair of through holes 541 of the pair of fixing portions 54 and then soldered therein. The protrusion members 1136 are received in the corresponding cutouts 542 of the lower sub-walls 5d.

The slider member 61 is assembled to the second channel 1221 of the first mounting portion 12, with the pair of thin bar members 1231 of the two guiding members 123 received in the two grooves 613 of the slider member 61, the through hole 614 thereof aligning with guiding passages 1232 of the two guiding members 123, the opening 6120 between the arm portions 612 is facing towards the tab 1133 in the first channel 1132. Then, the actuator member 62 is assembled to the first mounting portion 12 of the base portion 12, and the pair of pivot members 1211 of the first mounting portion 12 are received in the pair of first positioning holes 6221 of the door jambs 622 of the actuator member 62, the pair of mounting holes 6222 located in the end section of the door jambs 622 are aligning with the through hole 614 of the slider member 61 and the through holes 1232 of the two guiding members 123, then the bolt member 631 is inserted through the pair of mounting holes 6222, the through holes 614 and the guiding passages 1232, and the nut 632 is finally assembled to end of the bolt member 631.

When the electronic module 100 mating with the complementary connector (not shown), the elastic detents 52 contact with a cage (not shown) of the complementary connector to reduce EMI nearby an interface between a front segment of the complementary connector and rear portions of the primary body portion 11 of the base portion 1 and the secondary body portion 21 of the panel portion 2, and the seamless frame portion 51 can integrally shield inside of the elastic detents 52 to further prevent EMI leakage through slits between adjacent elastic detents 52.

While the electronic module 100 disengaging away from the complementary connector, just exert a pulling force on the handle member 623 of the actuator member 62 to promote the slider member 61 moving forwardly to reversely push the electronic module 100 moving backwards to depart from the complementary connector.

It is to be understood, however, that even though numerous characteristics and advantages of the present invention have been set forth in the foregoing description, together with details of the structure and function of the invention, the disclosure is illustrated only, and changes may be made in detail, especially in matters of shape, size, and arrangement of parts within the principles of the invention to the full extent indicated by the broad general meaning of the terms in which the appended claims are expressed.

What is claimed is:

1. An electronic module, comprising:
a housing having an outer surface;
a metallic gasket attached to the housing and substantially covering the outer surface; and
wherein the gasket includes an outer configuration with a plurality of elastic detents and a unitary inner configuration with a seamless sheet.

2. The electronic module as claimed in claim 1, wherein the inner configuration of the metallic gasket is defined as a frame portion, the elastic detents and the frame portion are pressed with a same metallic sheet, and the elastic detents are bent outwards and extending rearwards from front edges of the frame portion.

3. The electronic module as claimed in claim 2, wherein the housing includes a conductive base portion having a primary body portion defining a receiving space, and a conductive panel portion having a secondary body portion covering an upper window of the receiving space.

4. The electronic module as claimed in claim 3, wherein the primary body portion of the base portion includes a pair of lateral walls and a bottom wall joining to the pair of the lateral wall to from the receiving space, wherein the primary body portion has a beam portion with substantially L-shaped cross-section interconnecting free end portions of the pair of the lateral walls, and wherein the secondary body portion of the panel portion has a protrusion portion formed at forward end thereof disposed on the beam portion.

5. The electronic module as claimed in claim 4, wherein rear segments of the pair of the lateral walls of the primary body portion define first depression portions, and a rear segment of the secondary body portion of the secondary body portion defines second depression portion.

6. The electronic module as claimed in claim 5, wherein frame portion includes a pair of vertical sides and an upper side joining upper edges of the pair of vertical sides, and the vertical sides are located in the pair of first depression portions of the base portion, the upper side is located in the second depression portion of the panel portion.

7. The electronic module as claimed in claim 3, wherein a printed circuit board is located in the receiving space and fixed to the conductive panel portion.

8. The electronic module as claimed in claim 3, wherein the base portion further includes first mounting portion rearward extending from back face of the primary body portion, and the panel portion further includes second mounting portion rearward extending from back face of the secondary body portion.

9. The electronic module as claimed in claim 8, wherein the first mounting portion defines a first semi-circular cavity, wherein the second mounting portion defines a second semi-circular cavity, and wherein a cable is inserted into the receiving space via the first and second cavities.

10. The electronic module as claimed in claim 9, wherein the first mounting portion defines a first position slot in a front portion of the first semi-circular cavity, wherein the second mounting portion defines a second position slot in front of the second semi-circular cavity, the cable is disposed in the first position slot and the second position slot.

11. The electronic module as claimed in claim 1, further comprising an actuate mechanism.

12. The electronic module as claimed in claim 11, wherein the actuator mechanism includes a slider member located in a channel of rear section of the base portion, an actuator member pivotally engaged with the base portion and a fastening member linkaged the slider member and the actuator member.

13. The electronic module as claimed in claim 12, further comprises a pair of guiding members respectively formed on rear section of the base portion, laterally arranged the channel of the base portion.

14. The electronic module as claimed in claim 13, wherein each of guiding member has a bar member formed on a back section of the inward surface thereof and a lengthways guiding passage in front of the bar member.

15. The electronic module as claimed in claim 14, wherein the slider member includes a body portion having two grooves respectively recessed inward from lateral surfaces of a rear segment thereof and a transverse through hole in a middle section thereof, in front of the grooves.

16. The electronic module as claimed in claim 15, wherein the actuator member is configured to doorframe-shaped, including a doorhead with handle member formed thereon and two door jambs having a pair of mounting holes defined through the lower ends thereof.

17. The electronic module as claimed in claim 16, wherein the bar members of the pair of guiding member received in the two grooves of the base portion of the slider member respectively, wherein the mounting holds of the actuator aligning with the guiding passages of the pair of the guiding members and the transverse through hole of the slider member to allow the fastening member pass through.

18. An electronic module comprising:
a housing surrounded by a plurality of exterior faces;
an actuator mechanism located on a front portion of the housing;
a metallic gasket located closely behind the actuator and covering at least some of said exterior faces; wherein
said gasket includes an inner layer essentially intimately abutting against the exterior faces, and an outer layer defining a plurality of outwardly and obliquely extending engagement fingers under condition that the inner layer and the outer layer are unified with each other by sharing a common rear edge in a folded manner.

19. The electronic module as claimed in claim 18, wherein the inner layer extends with a complete plane seamlessly on each corresponding exterior face.

20. The electrical module as claimed in claim 18, wherein a plurality of cutouts are formed in the common rear edge for easing folding between the inner layer and the outer layer.
